(19) United States
(12) Patent Application Publication
(10) Pub. No.: US 2014/0319482 A1
(43) Pub. Date: Oct. 30, 2014

(54) LIGHT-EMITTING COMPONENT AND METHOD FOR PRODUCING A LIGHT-EMITTING COMPONENT

(71) Applicants: Thomas Dobbertin, Regensburg (DE); Erwin Lang, Regensburg (DE); Thilo Reusch, Regensburg (DE); Daniel Steffen Setz, Boeblingen (DE)

(72) Inventors: Thomas Dobbertin, Regensburg (DE); Erwin Lang, Regensburg (DE); Thilo Reusch, Regensburg (DE); Daniel Steffen Setz, Boeblingen (DE)

(73) Assignee: OSRAM OPTO SEMICONDUCTORS GMBH, Regensburg (DE)

(21) Appl. No.: 14/131,922

(22) PCT Filed: May 31, 2012
(86) PCT No.: PCT/EP2012/060282

§ 371 Date: Mar. 14, 2014

(30) Foreign Application Priority Data
Jul. 13, 2011 (DE) 10 2011 079 063.2

(51) Int. Cl. H01L 51/52; H01L 51/56

(52) U.S. Cl. CPC H01L 51/5268; H01L 51/56; H01L 51/5271
USPC 257/40; 438/29

(57) ABSTRACT

A light-emitting component may include: a first electrode; an organic electroluminescent layer structure on or above the first electrode; a second translucent electrode on or above the organic electroluminescent layer structure; an optically translucent layer structure on or above the second electrode, wherein the optically translucent layer structure includes photoluminescence material; and a mirror layer structure on or above the optically translucent layer structure.

### RELATED APPLICATIONS

The present application is a national stage entry according to 35 U.S.C. §371 of PCT application No.: PCT/EP2012/060282 filed on May 31, 2012, which claims priority from German application No.: 10 2011 079 063.2 filed on Jul. 13, 2011, and is incorporated herein by reference in its entirety.

### TECHNICAL FIELD

Various embodiments relate to a light-emitting component and a method for producing a light-emitting component.

### BACKGROUND

In organic light-emitting diodes (OLEDs) light is generated for example by means of electroluminescence of organic color centers (chromophores) in an organic matrix. Said organic matrix is usually situated in a layer stack including organic transport materials and at least two electrically conductive electrodes, for example on a substrate. Of the two electrically conductive electrodes, at least one electrically conductive electrode is translucent, for example transparent, and together with the layer stack and the second electrically conductive electrode forms an optical microcavity, if appropriate in conjunction with additional dielectric layers for optical adaptation, which may likewise be part of an organic light-emitting diode.

The selection of the color centers and organic materials and the construction of the layer stack influence the characteristic data of the OLED, such as, for example, its efficiency, lifetime and color rendering index (CRI). An optimization of the color centers and of the layer stack with regard to the color rendering index generally requires compromises with regard to the other characteristic data and possibly complex adaptation and coordination of the organic matrix materials and organic transport materials in the layer stack. Coordination of the color temperature of an OLED tile, having one or a plurality of OLEDs, for specific customer desires is comparably complex.

In an organic light-emitting diode, the color rendering and the color temperature are usually set by adaptation of the organic system layer stack and the optical microcavity (including the electrically conductive electrodes and the antireflection layers likewise provided, if appropriate). On account of many mutual dependencies of the electrical and optical properties, however, this has been able to be achieved heretofore only with comparatively high development outlay.

### SUMMARY

Various embodiments provide a light-emitting component. The light-emitting component may include a first translucent electrode; an organic electroluminescent layer structure on or above the first electrode; a second translucent electrode on or above the organic electroluminescent layer structure; an optically translucent layer structure on or above the second translucent electrode, wherein the optically translucent layer structure includes photoluminescence material; and a mirror layer structure on or above the optically translucent layer.

Various embodiments provide a light-emitting component in which a high degree of design freedom with regard to the material selection for the optically translucent layer structure and the photoluminescence material contained therein is obtained since this layer structure and the photoluminescence material contained therein require only the property of photoluminescence, but not the property of electroluminescence, although the latter may optionally likewise be present.

In various embodiments, therefore, illustratively the optically translucent layer structure or the photoluminescence material is not pumped with electric current, but rather predominantly or exclusively with light.

In various embodiments, the term “translucent” or “translucent layer” may be understood to mean that a layer is transmissive to light, for example to the light generated by the light-emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light may be scattered in this case.

In various embodiments, the term “transparent layer” may be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, “transparent” should be regarded as a special case of “translucent”.

For the case where, for example, a light-emitting monochromatic or emission spectrum-limited electronic component is intended to be provided, it suffices for the optically translucent layer structure to be translucent in the to radiation at least in a partial range of the wavelength range of the desired monochromatic light or for the limited emission spectrum.

In one configuration, the second electrode may be designed in such a way that the optically translucent layer structure is optically coupled to the organic electroluminescent layer structure.

In another configuration, the photoluminescence material may include a material from at least one of the following material groups: organic dye molecules; inorganic phosphors; nanodots; nanoparticles.

In another configuration, an electrically insulating layer may be provided between the second electrode and the optically translucent layer structure.

In another configuration, a barrier layer/thin-film encapsulation may be between the second electrode and the optically translucent layer structure.

In another configuration, the refractive index of the optically translucent layer structure may be substantially adapted to the refractive index of the organic electroluminescent layer structure.

In another configuration, the optically translucent layer structure may additionally include one or a plurality of scattering materials.

Various embodiments provide a light-emitting component. The light-emitting component may include a mirror layer structure; an optically translucent layer structure on or above the mirror layer structure, wherein the optically translucent layer structure includes photoluminescence material; a first translucent electrode on or above the optically translucent layer structure; an organic electroluminescent layer structure on or above the first electrode; and a second translucent electrode on or above the organic electroluminescent layer structure.

In another configuration, the light-emitting component may furthermore include an electrically insulating layer between the first translucent electrode and the optically translucent layer structure.

In another configuration, the light-emitting component may furthermore include a barrier layer/thin-film encapsulation between the first electrode and the optically translucent layer structure.

Various embodiments provide a method for producing a light-emitting component. The method may include providing a first translucent electrode; forming an organic electroluminescent layer structure on or above the first electrode; forming a second translucent electrode on or above the organic electroluminescent layer structure; forming an optically translucent layer structure on or above the second electrode, wherein photoluminescence material are formed in the optically translucent layer structure; and forming a mirror layer structure on or above the optically translucent layer.

In one configuration, the second electrode may be formed in such a way that the optically translucent layer structure is optically coupled to the organic electroluminescent layer structure.

In another configuration, a material from at least one of the following material groups may be used as photoluminescence material: organic dye molecules; inorganic phosphors; nanodots; nanoparticles.

In another configuration, the method may furthermore include forming an electrically insulating layer on or above the second electrode; wherein the optically translucent layer structure may be formed on or above the electrically insulating layer.

In another configuration, the method may furthermore include forming a barrier layer (optionally subsequently forming a thin-film encapsulation, in order to protect the electroluminescent layers.

In another configuration, the refractive index of the optically translucent layer structure may be substantially adapted to the refractive index of the organic electroluminescent layer structure.

In another configuration, the optically translucent layer structure may additionally include one or a plurality of scattering materials.

In another configuration, the optically translucent layer structure may be formed by means of vapor deposition.

In another configuration, the photoluminescence material may be embedded in situ into the optically translucent layer structure, for example in situ during vapor deposition.

In another configuration, the optically translucent layer structure may be formed by means of a wet-chemical process.

Various embodiments provide a method for producing a light-emitting component. The method may include providing a mirror layer structure; forming an optically translucent layer structure on or above the mirror layer structure, wherein photoluminescence material is formed in the optically translucent layer structure; forming a first translucent electrode on or above the optically translucent layer structure; forming an organic electroluminescent layer structure on or above the first electrode; and forming a second translucent electrode on or above the organic electroluminescent layer structure.

In one configuration, the method may furthermore include forming an electrically insulating layer on or above the optically translucent layer structure; wherein the first electrode is formed on or above the electrically insulating layer.

In another configuration, the method may furthermore include forming a barrier layer (optionally furthermore subsequently forming a thin-film encapsulation, in order to protect the electroluminescent layers).

One advantage of various embodiments illustratively arises from the different degrees of freedom for varying the color components of the light emitted from the OLED cavity, without intervening in the electrical function of the OLED (generally the light-emitting component). As a result, firstly more different color centers than was previously possible in the conventional OLED layer stacks may simultaneously contribute to the generation of light. Secondly, the approach in accordance with various embodiments increases the selection of possible chromophores since it does not impose any restrictions with regard to electrical transport and electroluminescence. The essential properties of the chromophores in the external cavity (cavities) in accordance with various embodiments are quantum efficiency and excitation and emission spectrum. By way of example, inorganic chromophores may also be used. A suitable selection from a plurality of color centers with complementary emission spectra enables a high color rendering and simplified coordination of the color temperature and a reduction of the outlay in product development.

The arrangement of the color centers in an external cavity in accordance with various embodiments makes it possible to achieve a higher light conversion efficiency than is possible for example with phosphors on the surface of an OLED component.

Furthermore, the arrangement of the color centers within the external cavity in accordance with various embodiments makes it possible to obtain a variation of the color distortion over the viewing angle. In this case too, the color centers may be arranged according to purely optical criteria, without consideration of their electrical transport properties, as was necessary in previous purely electroluminescent OLED layer stacks.

Further possible advantages in accordance with various embodiments are a higher efficiency and lifetime of the light-emitting component. This may be achieved by virtue of the fact that electroluminescent color centers with limited efficiency and lifetime may be replaced, if appropriate, by photoluminescent color centers in the one or the plurality of external cavities.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a light-emitting component in accordance with various embodiments;

FIG. 2 shows a light-emitting component in accordance with various embodiments;

FIG. 3 shows a light-emitting component in accordance with various embodiments;

FIG. 4 shows a light-emitting component in accordance with various embodiments;

FIG. 5 shows a light-emitting component in accordance with various embodiments; and

FIGS. 6A to 6F show a light-emitting component in accordance with various embodiments at different points in time during the production of said component.

### DETAILED DESCRIPTION

In the following detailed description, reference is made to the accompanying drawings, which form part of this description and show for illustration purposes specific embodiments in which the disclosure may be implemented. In this regard, direction terminology such as, for instance, “at the top”, “at the bottom”, “at the front”, “at the back”, “front”, “rear”, etc. is used with respect to the orientation of the figure(s) described. Since component parts of embodiments may be positioned in a number of different orientations, the direction terminology serves for illustration and is not restrictive in any way whatsoever. It goes without saying that other embodiments may be used and structural or logical changes may be made, without departing from the scope of protection of the present disclosure. It goes without saying that the features of the various embodiments described herein may be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In various embodiments, a light-emitting component may be embodied as an organic light-emitting diode (OLED), or as an organic light-emitting transistor. In various embodiments, the light-emitting component may be part of an integrated circuit. Furthermore, a plurality of light-emitting components may be provided, for example in a manner accommodated in a common housing.

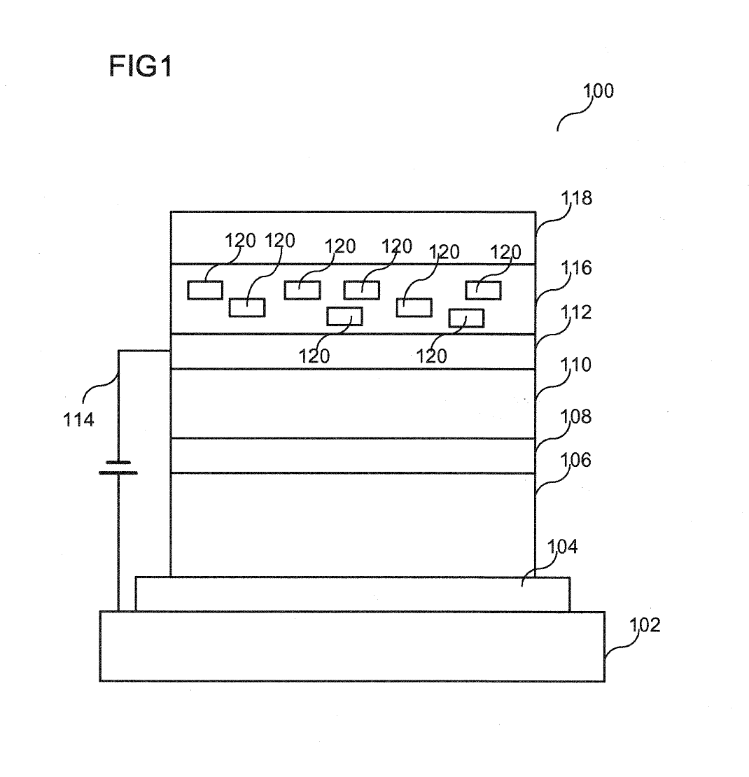

FIG. 1 shows an organic light-emitting diode 100 as an implementation of a light-emitting component in accordance with various embodiments.

The light-emitting component in the form of an organic light-emitting diode 100 may have a substrate 102. The substrate 102 may serve for example as a carrier element for electronic elements or layers, for example light-emitting elements. By way of example, the substrate 102 may include or be formed from glass, quartz, and/or a semiconductor material or any other suitable material. Furthermore, the substrate 102 may include or be formed from a plastic film or a laminate including one or including a plurality of plastic films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). Furthermore, the substrate 102 may include for example a metal film, for example an aluminum film, a high-grade steel film, a copper film or a combination or a layer stack thereon. The substrate 102 may include one or more of the materials mentioned above. The substrate 102 may be embodied as translucent for example transparent, partly translucent, for example partly transparent, or else opaque.

A first electrode 104 (for example in the form of a first electrode layer 104) may be applied on or above the substrate 102. The first electrode 104 (also designated hereinafter as bottom electrode 104) may be formed from an electrically conductive material, such as, for example, a metal or a transparent conductive oxide (TCO) or a layer stack including a plurality of layers of the same or different metal or metals and/or the same or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₂, ZnSnO₂, MgIn₂O₄, GaInO₃, Zn₂In₂O₅ or In₄Sn₃O₁₂, or mixtures of different transparent conductive oxides also belong to the group of TCOs. Furthermore, the TCOs do not necessarily correspond to a stoichiometric composition and may furthermore be p-doped or n-doped.

In various embodiments, the first electrode 104 may include a metal, for example Ag, Pt, Au, Mg, Al, Ba, In, Au, Ca, Sm or Li, and compounds, combinations or alloys of these materials (for example an AgMg alloy).

In various embodiments, the first electrode 104 may be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode may provide one or a plurality of the following materials as an alternative or in addition to the above-mentioned materials: networks composed of metallic nanowires and nanoparticles, for example composed of Ag; networks composed of carbon nanotubes; graphene particles and graphene layers; networks composed of semiconducting nanowires.

Furthermore, said electrodes may include conductive polymers or transition metal oxides or transparent conductive oxides.

In various embodiments, the organic light-emitting diode may be designed as a so-called top emitter and/or as a so-called bottom emitter. In various embodiments, a top emitter may be understood to be an organic light-emitting diode in which the light is emitted from the organic light-emitting diode through the side or cover layer situated opposite the substrate, for example through the second electrode. In various embodiments, a bottom emitter may be understood to be an organic light-emitting diode in which the light is emitted from the organic light-emitting diode toward the bottom, for example through the substrate and the first electrode.

In various embodiments, the first electrode 104 may be embodied as reflective or translucent or transparent.

For the case where the light-emitting component 100 emits light through the substrate, the first electrode 104 and the substrate 102 may be formed as translucent or transparent. In this case, for the case where the first electrode 104 is formed from a metal, the first electrode 104 may have for example a layer thickness of less than or equal to approximately 25 nm, for example a layer thickness of less than or equal to approximately 20 nm, for example a layer thickness of less than or equal to approximately 18 nm. Furthermore, the first electrode 104 may have for example a layer thickness of greater than or equal to approximately 10 nm, for example a layer thickness of greater than or equal to approximately 15 nm. In various embodiments, the first electrode 104 may have a layer thickness in a range of approximately 10 nm to approximately 25 nm, for example a layer thickness in a range of approximately 10 nm to approximately 18 nm, for example a layer thickness in a range of approximately 15 nm to approximately 18 nm. Furthermore, for the case of a translucent or transparent first electrode 104 and for the case where the first electrode 104 is formed from a transparent conductive oxide (TCO), the first electrode 104 may have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm. Furthermore, for the case of a translucent or transparent first electrode 104 and for the case where the first electrode 104 is formed from, for example, a network composed of metallic nanowires, for example composed of Ag, which may be combined with conductive polymers, a network composed of carbon nanotubes which may be combined with conductive polymers, or from graphene layers and composites, the first electrode 104 may have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

For the case where the light-emitting component 100 emits light exclusively toward the top, the first electrode 104 may also be designed as opaque or reflective. For the case where the first electrode 104 is formed as reflective and from metal, the first electrode 104 may have a layer thickness of greater than or equal to approximately 40 nm, for example a layer thickness of greater than or equal to approximately 50 nm.

The first electrode 104 may be formed as an anode, that is to say as a hole-injecting electrode, or as a cathode, that is to say electron-injecting.

The first electrode 104 may have a first electrical terminal, to which a first electrical potential (provided by an energy store 114 (for example a current source or a voltage source) may be applied. Alternatively, the first electrical potential may be applied to the substrate 102 and then be fed indirectly to the first electrode 104 via said substrate. The first electrical potential may be, for example, the ground potential or some other predefined reference potential.

Furthermore, the light-emitting component 100 may have an organic electroluminescent layer structure, which is applied on or above the first electrode 104.

The organic electroluminescent layer structure may contain one or a plurality of emitter layers 108, for example including fluorescent and/or phosphorescent emitters, and one or a plurality of hole-conducting layers 106.

Examples of emitter materials which may be used in the light-emitting component in accordance with various embodiments for the emitter layer(s) 108 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl-(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium (III) complex) and blue fluorescent DPAVBi (4,4-bis[4-(di-p-tolylamino)styryl]biphenyl), green fluorescent TTPA (9,10-bis[N,N-di-(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters may be deposited by means of thermal evaporation, for example. Furthermore, it is possible to use polymer emitters, which may be deposited, in particular, by means of wet-chemical methods such as spin coating, for example.

The emitter materials may be embedded in a matrix material in a suitable manner.

The emitter materials of the emitter layer(s) 108 of the light-emitting component 100 may be selected for example such that the light-emitting component 100 emits white light. The emitter layer(s) 108 may include a plurality of emitter materials that emit in different colors (for example blue and yellow or blue, green and red); alternatively, the emitter layer(s) 108 may also be constructed from a plurality of partial layers, such as a blue fluorescent emitter layer 108 or blue phosphorescent emitter layer 108, a green phosphorescent emitter layer 108 and a red phosphorescent emitter layer 108. By mixing the different colors, the emission of light having a white color impression may result. Alternatively, provision may also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The organic electroluminescent layer structure may generally include one or a plurality of electroluminescent layers. The one or the plurality of electroluminescent layers may include organic polymers, organic oligomers, organic monomers, organic small, non-polymeric molecules (“small molecules”) or a combination of these materials.

By way of example, the organic electroluminescent layer structure may include one or a plurality of functional layers embodied as a hole transport layer 106, so as to enable for example in the case of an OLED an effective hole injection into an electroluminescent layer or an electroluminescent region.

For example, in various embodiments, the organic electroluminescent layer structure may include one or a plurality of functional layers embodied as an electron transport layer 106, so as to enable for example in the case of an OLED an effective electron injection into an electroluminescent layer or an electroluminescent region.

By way of example, tertiary amines, carbazo derivatives, conductive polyaniline or polyethylene dioxythiophene may be used as material for the hole transport layer 106. In various embodiments, the one or the plurality of functional layers may be embodied as an electroluminescent layer.

In various embodiments, the hole transport layer 106 may be applied, for example deposited, on or above the first electrode 104, and the emitter layer 108 may be applied, for example deposited, on or above the hole transport layer 106.

In various embodiments, the organic electroluminescent layer structure (that is to say for example the sum of the thicknesses of transport layer(s) 106 and emitter layer(s) 108) may have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure may have for example a stack of a plurality OLEDs arranged directly one above another, wherein each OLED may have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure may have for example a stack of three or four OLEDs arranged directly one above another, in which case for example the organic electroluminescent layer structure may have a layer thickness of a maximum of approximately 3 μm.

The light-emitting component 100 may optionally generally include further organic functional layers (symbolized by means of a layer 110 in FIG. 1, arranged on or above the one or the plurality of emitter layers 108), which serve to further improve the functionality and thus the efficiency of the light-emitting component 100.

The light-emitting component 100 may be embodied as a “bottom emitter” and/or “top emitter”.

A second electrode 112 (for example in the form of a second electrode layer 112) may be applied on or above the organic electroluminescent layer structure or, if appropriate, on or above the one or the plurality of further organic functional layers 110.

In various embodiments, the second electrode 112 may include or be formed from the same materials as the first electrode 104, metals being particularly suitable in various embodiments.

In various embodiments, the second electrode 112 may have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 112 may generally be formed in a similar manner to the first electrode 104, or differently than the latter. In various embodiments, the second electrode 112 may be formed from one or more of the materials and with the respective layer thickness (depending on whether the second electrode is intended to be formed as reflective, translucent or transparent) as described above in connection with the first electrode 104.

The second electrode 112 may be formed as an anode, that is to say as a hole-injecting electrode, or as a cathode, that is to say electron-injecting.

In the case of these layer thicknesses, the additional microcavity, explained in even greater detail below, may be optically coupled to the microcavity (microcavities) formed by the one or the plurality of electroluminescent layer structures.

The second electrode 112 may have a second electrical terminal, to which a second electrical potential (which is different than the first electrical potential), provided by the energy source 114, may be applied. The second electrical potential may have for example a value such that the difference with respect to the first electrical potential has a value in a range of approximately 1.5 V to approximately 20 V, for example a value in a range of approximately 2.5 V to approximately 15 V, for example a value in a range of approximately 5 V to approximately 10 V.

An optically translucent layer structure 116 may be provided on or above the second electrode 112. The optically translucent layer structure 116 may include photoluminescence material 120.

The optically translucent layer structure 116 may be formed from an arbitrary material, in principle, for example a dielectric material, for example an organic material, which forms an organic matrix, for example, into which the photoluminescence material 120 may be embedded. A mirror layer structure 118 is applied on or above the optically translucent layer structure 116. Illustratively, the optically translucent layer structure 116 and the mirror layer structure 118 jointly form a photoluminescent cavity, for example microcavity, optically coupled (that is to say illustratively external) to the electroluminescent microcavity of the light-emitting component 100, for example the OLED, having one optically active medium or a plurality of optically active media.

In various embodiments, the optically translucent layer structure 116 is translucent to radiation at least in a partial range of the wavelength range of 380 nm to 780 nm.

For this purpose for example in this embodiment the optically translucent layer structure 116 of the “external” photoluminescent cavity is brought into contact with the translucent, transparent or semitransparent second electrode 112 of the OLED microcavity. The “external” photoluminescent cavity does not participate or participates only insignifimaytly in the current transport through the OLED; to put it another way, no or only a negligibly small electric current flows through the “external” cavity and thus through the optically translucent layer structure 116 and the mirror layer structure 118.

As already set out above, the “external” photoluminescent cavity, and in this case in particular the optically translucent layer structure 116, in various embodiments, may be “filled” with a suitable organic matrix or be formed by such, in which photoluminescence material 120 may be embedded; for example, the organic matrix may be doped with organic or inorganic chromophores and phosphors. The “external” photoluminescent cavity may have two mirrors or mirror layer structures, at least one of which is translucent, transparent or semitransparent. The translucent, transparent or semitransparent mirror (or the translucent, transparent or semitransparent mirror layer structure) may be identical to the translucent, transparent or semitransparent second electrode 112 of the OLED microcavity (these embodiments are illustrated in the figures; in alternative embodiments, however, an additional translucent, transparent or semitransparent mirror layer structure may also be provided between the second electrode 112 and the optically translucent layer structure 116).

In various embodiments, low molecular weight organic compounds (“small molecules”) may be provided as material for the organic matrix, and may be applied for example by means of vapor deposition in vacuo, such as alpha-NPD or 1-TNATA, for example. In alternative embodiments, the organic matrix may be formed from or consist of polymeric materials which for example form an optically transparent polymeric matrix (epoxides, polymethyl methacrylate, PMMA, EVA, polyester, polyurethanes, or the like) and may be applied by means of a wet-chemical method (for example spin coating or printing). In various embodiments, for example any organic material such as may also be used in the organic electroluminescent layer structure may be used for the organic matrix. Furthermore, in alternative embodiments, the optically translucent layer structure 116 may include or be formed by an inorganic semiconductor material, for example SiN, SiO₂, GaN, etc., which for example by means of a low-temperature deposition method (for example from the gas phase) (i.e. for example at a temperature of less than or equal to approximately 100° C.). In various embodiments, the refractive indices of the OLED functional layers 106, 108 and of the optically translucent layer structure 116 may be adapted to one another as much as possible, wherein the optically translucent layer structure 116 may also include high refractive index polymers, for example polyimides having a refractive index of up to n=1.7, or polyurethane having a refractive index of up to n=1.74.

In various embodiments, additives may be provided in the polymers. Therefore, illustratively, a high refractive index polymer matrix may be achieved by mixing suitable additives into a polymeric matrix having a normal refractive index. Suitable additives are, for example, titanium oxide or zirconium oxide nanoparticles or compounds including titanium oxide or zirconium oxide.

In various embodiments, between the second translucent electrode 112 and the optically translucent layer structure 116 an electrically insulating layer may also be applied, for example SiN, for example having a layer thickness in a range of approximately 30 nm to approximately 1.5 μm, for example having a layer thickness in a range of approximately 200 nm to approximately 1 μm, in order to protect electrically unstable materials, for example during a wet-chemical process.

In various embodiments, a barrier thin-film layer/thin-film encapsulation may optionally also be formed.

In the context of this application, a “barrier thin-film layer” or a “barrier thin film” may be understood to mean, for example, a layer or a layer structure which is suitable for forming a barrier against chemical impurities or atmospheric substances, in particular against water (moisture) and oxygen. In other words, the barrier thin-film layer is formed in such a way that OLED-damaging substances such as water, oxygen or solvent may not penetrate through it or at most very small proportions of said substances may penetrate through it. Suitable configurations of the barrier thin-film layer may be found for example in the patent applications DE 10 2009 014 543 A1, DE 10 2008 031 405 A1, DE 10 2008 048 472 A1 and DE 2008 019 900 A1.

In accordance with one configuration, the barrier thin-film layer may be formed as an individual layer (to put it another way, as a single layer). In accordance with an alternative configuration, the barrier thin-film layer may include a plurality of partial layers formed one on top of another. In other words, in accordance with one configuration, the barrier thin-film layer may be formed as a layer stack. The barrier thin-film layer or one or a plurality of partial layers of the barrier thin-film layer may be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range may be deposited.

In accordance with one configuration, in the case of a barrier thin-film layer having a plurality of partial layers, all the partial layers may be formed by means of an atomic layer deposition method. A layer sequence including only ALD layers may also be designated as a “nanolaminate”.

In accordance with an alternative configuration, in the case of a barrier thin-film layer including a plurality of partial layers, one or a plurality of partial layers of the barrier thin-film layer may be deposited by means of a different deposition method than an atomic layer deposition method, for example by means of a vapor deposition method.

In accordance with one configuration, the barrier thin-film layer may have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer includes a plurality of partial layers, all the partial layers may have the same layer thickness. In accordance with another configuration, the individual partial layers of the barrier thin-film layer may have different layer thicknesses. In other words, at least one of the partial layers may have a different layer thickness than one or more other partial layers.

In accordance with one configuration, the barrier thin-film layer or the individual partial layers of the barrier thin-film layer may be formed as a translucent or transparent layer. In other words, the barrier thin-film layer (or the individual partial layers of the barrier thin-film layer) may consist of a translucent or transparent material (or a material combination that is translucent or transparent).

In accordance with one configuration, the barrier thin-film layer or (in the case of a layer stack having a plurality of partial layers) one or a plurality of the partial layers of the barrier thin-film layer may include or consist of one of the following materials: aluminum oxide, zinc oxide, zirconium oxide, titanium oxide, hafnium oxide, tantalum oxide, lanthanium oxide, silicon oxide, silicon nitride, silicon oxynitride, indium tin oxide, indium zinc oxide, aluminum-doped zinc oxide, and mixtures and alloys thereof.

The photoluminescence material 120 may include or consist of a material from at least one of the following material groups: organic dye molecules; inorganic phosphors; and/or nanodots or nanoparticles.

Organic dye molecules should be understood to mean, for example, all molecules which may also be used in the organic electroluminescent layer structure, for example the electroluminescent (fluorescent or phosphorescent) materials which have been described above. However, organic dye molecules also encompass the molecules which have predominantly or exclusively photoluminescent properties. They may also encompass the dyes which are used for example in dye lasers or as fluorescence markers, such as, for example, fluorescent dyes: coumarins, naphthals, oxazoles, perylenes, perylene bisimides, pyrenes, stilbenes, styryls, xanthans.

Inorganic phosphors should be understood to mean, for example, all materials which are used for light conversion in a light-emitting diode (LED) for example, or in a fluorescent tube, such as for example
inherently typical phosphors for LEDs, such as for example phosphors based on YAG:Ce³⁺; wherein Eu, Tb, Gd or further rare earths may also be doped instead of Ce, wherein parts of the Al may be replaced by Ga, for example: (Y₁₋ₐGdₐ) (Al_{1-b}Ga_{b})₅O₁₂: (Ce, Tb, Gd); β-SiAlON doped with rare earths; CaAlSiN3-based phosphors; and mixtures and alloys of these materials; or
inherently typical phosphors for fluorescent lamps such as for example (Ba, Eu)Mg₂Al₁₆O₂₇; (Ce, Tb)MgAl₁₁O₁₉; BaMgAl₁₀O₁₇:Eu, Mn; BaMg₂Al₁₆O₂₇:Eu (II), Mn (II); Ce_{0.67}Tb_{0.33}MgAl₁₁O₁₉:Ce, Tb; Zn₂SiO₄:Mn, Sb₂O₃; CaSiO₃:Pb, Mn; CaWO₄; CaWO₄: Pb; MgWO₄; (Sr, Eu, Ba, Ca)₅)(PO₄)₃Cl; Sr₅Cl(PO₄)₃:Eu (II); (Ca, Sr, Ba)₃(PO₄)₂Cl₂:Eu; (Sr, Ca, Ba)₁₀(PO₄)₆Cl₂;Eu; Sr₂P₂O₇: Sn (II); Sr₆P₅BO₂₀:Eu; Ca₅F (PO₄)₃: Sb; (Ba, Ti)₂P₂O₇:Ti; 3Sr₃(PO₄)₂.SrF₂: Sb, Mn; Sr₅F (PO₄)₃: Sb, Mn; Sr₅F (PO₄)₃: Sb, Mn; (La, Ce, Tb) PO₄; (La, Ce, Tb) PO₄:Ce, Tb; Ca₃(PO₄)₂.CaF₂:Ce, Mn; (Ca, Zn, Mg)₃(PO₄)₂:Sn; (Zn, Sr)₃(PO₄)₂:Mn; (Sr, Mg)₃(PO₄)₂:Sn; (Sr, Mg)₃(PO₄)₂:Sn (II); Ca₅(F, Cl)(PO₄)₃: Sb, Mn; (Y, Eu)₂O₃; Y₂O₃:Eu (III); Mg₄ (F) (Ge, Sn)O₆:Mn; Y(P, V) O₄:Eu; Y₂O₂S:Eu; 3.5 MgO.0.5MgF₂.GeO₂:Mn; Mg₅As₂O₁₁:Mn, and mixtures and alloys of these materials.

Nanodots should be understood to mean, for example, all materials which may be used as nanodots, for example semiconducting nanoparticles, such as silicon nanodots or nanodots composed of compound semiconductors, for example chalcogenides (selenides or sulfides or tellurides) of metals such as for example cadmium or zinc (CdSe or ZnS, copper indium gallium diselenide, copper indium diselenide, for example including so-called core-shell nanodots, or CuInS₂/ZnS. Nanoparticles may also include phosphor nanoparticles, for example.

Generally, any arbitrary suitable light conversion material which is designed to convert a light wavelength may be used as the photoluminescence material 120.

The photoluminescence material 120 may be present in the optically translucent layer structure 116 in a concentration in a range of approximately 0 to approximately 50 percent % by volume, for example in a range of approximately 1 to approximately 20 percent % by volume, for example in a range of approximately 1 to approximately 10 percent % by volume.

The photoluminescence material 120 may provide color centers which, on account of the photoluminescence, may vary the color components of the light emitted from the OLED cavity. As described above, the photoluminescence material 120 may also include inorganic chromophores, such as for example small phosphor particles or quantum dots (nanodots) or nanoparticles, introduced into the optically translucent layer structure 116 (for example into the organic matrix).

In addition to the photoluminescent material 120 (that is to say illustratively in addition to the for example fluorescent or phosphorescent constituents), the optically translucent layer structure 116 may contain additional scattering particles, for example dielectric scattering particles such as, for example, metal oxides such as e.g. silicon oxide (SiO2), zinc oxide (ZnO), zirconium oxide (ZrO2), indium tin oxide (ITO) or indium zinc oxide (IZO), gallium oxide (Ga2Oa), aluminum oxide or titanium oxide. Other particles may also be suitable provided that they have a refractive index that differs from the effective refractive index of the matrix of the translucent layer structure, for example air bubbles, acrylate, or hollow glass beads. Further, for example metallic nanoparticles may be provided, for example including metals such as gold, silver, iron nanoparticles or the like, wherein the scattering particles may be coated or uncoated. The scattering particles may be designed or be provided for varying the angular distribution of the light emitted by the light-emitting component 100 and, if appropriate, also for improving the color shift with the viewing angle.

In various embodiments, the optically translucent layer structure 116 may have a layer thickness in a range of approximately 10 nm to approximately 200 μm, for example a layer thickness in a range of approximately 100 nm to approximately 100 μm, for example a layer thickness in a range of approximately 500 nm to approximately 50 μm, for example 1 μm to 25 μm. If the optically translucent layer structure 116 is made very thin, then the photoluminescence material 120 is optically strongly coupled to the light field (in this case, the external cavity may also be designated as an external microcavity). However, if the optically translucent layer structure 116 is made thicker, then it is possible to achieve, for example, a low color angle distortion over the viewing angle (in this case, the external cavity may also be designated as an external incoherent cavity).

The limiting case of a very thin and very transparent or translucent external cavity may be seen in the photoluminescence material 120 (that is to say, for example the photoluminescent chromophores) in the optically translucent layer structure 116 (that is to say, for example, in the matrix) being applied directly on the top contact (for example the second translucent electrode 112) or between the bottom contact (for example the first electrode 104) and the substrate 102 (as in an embodiment explained in even greater detail below). The “second” mirror or the “second” mirror layer structure of the external cavity may be omitted in this case.

One possible advantage of this arrangement, which in various embodiments also forms the “external” photoluminescent cavity in the front-end-of-line processes, compared with a cavity applied by means of a back-end-of-line process on the outside of the inherently completed light-emitting component, may be seen in the strong optical coupling of the photoluminescence material 120 (that is to say, for example, the chromophores) to the plasmons in the OLED bottom contact (for example the first electrode 104) or in the OLED top contact (for example the second electrode 112).

The organic light-emitting diode 100 may be embodied as a bottom emitter or as a top emitter or as a top and bottom emitter.

In various embodiments, the mirror layer structure 118 (or, if appropriate, the mirror layer structure that may be provided on or above the second translucent electrode 112 below the optically translucent layer structure 116) may be reflective or translucent or transparent or semitransparent, depending on whether the organic light-emitting diode 100 is embodied as a top emitter and/or as a bottom emitter. The materials may be selected from the materials such as have been mentioned above for the first electrode. The layer thicknesses, too, depending on the desired embodiment of the organic light-emitting diode 100, may be chosen in the ranges such as have been described above for the first electrode.

For the case where the light-emitting component 100 emits light predominantly or exclusively toward the top (top emitter) and the mirror layer structure is formed from metal, the mirror layer structure 118 (or, if appropriate, the mirror layer structure that may be provided on or above the second translucent electrode 112 below the optically translucent layer structure 116) may include one or a plurality of thin metal films (for example Ag, Mg, Sm, Ca, and multilayers and alloys of these materials). The one or the plurality of metal films may have (in each case) a layer thickness in a range of less than 40 nm, for example a layer thickness in a range of less than 25 nm, for example a layer thickness in a range of less than 15 nm.

For the case where the light-emitting component 100 emits light predominantly or exclusively toward the bottom through the substrate 102 and the mirror layer structure is formed from metal, then the mirror layer structure 118 may have for example a layer thickness of greater than or equal to approximately 40 nm, for example a layer thickness of greater than or equal to approximately 50 nm.

In various embodiments, the mirror layer structure 118 (or, if appropriate, the mirror layer structure that may be provided on or above the second translucent electrode 112 below the optically translucent layer structure 116) may have one or a plurality of dielectric mirrors.

The mirror layer structure 118 may have one or a plurality of mirrors. If the mirror layer structure 118 has a plurality of mirrors, then the respective mirrors are separated from one another by means of a respective dielectric layer.

Furthermore, the organic light-emitting diode 100 may also have encapsulation layers, which may be applied for example in the context of a back-end-of-line process, wherein it should be pointed out that in various embodiments the external cavity is formed in the context still of the front-end-of-line process.

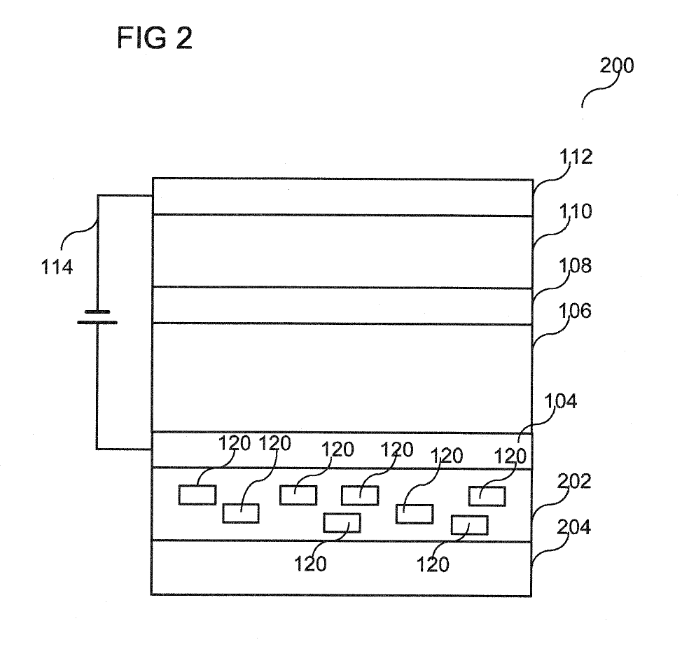

FIG. 2 shows an organic light-emitting diode 200 as an implementation of a light-emitting component in accordance with various embodiments.

The organic light-emitting diode 200 in accordance with FIG. 2 is substantially identical to the organic light-emitting diode 100 in accordance with FIG. 1, for which reason only the differences between the organic light-emitting diode 200 in accordance with FIG. 2 and the organic light-emitting diode 100 in accordance with FIG. 1 are explained in greater detail below; with regard to the remaining elements of the organic light-emitting diode 200 in accordance with FIG. 2, reference is made to the above explanations concerning the organic light-emitting diode 100 in accordance with FIG. 1.

In contrast to the organic light-emitting diode 100 in accordance with FIG. 1, in the case of the organic light-emitting diode 200 in accordance with FIG. 2, the external cavity is not formed on or above the second electrode 112, but rather below the first electrode 104.

In these embodiments, the energy source 114 is connected to the first electrical terminal of the first electrode 104 and to the second electrical terminal of the second electrode 112.

The organic light-emitting diode 200 in accordance with FIG. 2 may be formed as a bottom emitter or as a top emitter or as a top and bottom emitter.

In the case of the organic light-emitting diode 200 in accordance with FIG. 2, an optically translucent layer structure 202 constructed identically to the optically translucent layer structure 116 of the organic light-emitting diode 100 in accordance with FIG. 1 is arranged below the first electrode 104. Furthermore, a mirror layer structure 204 constructed identically to the mirror layer structure 118 of the organic light-emitting diode 100 in accordance with FIG. 1 is arranged below the optically translucent layer structure 202.

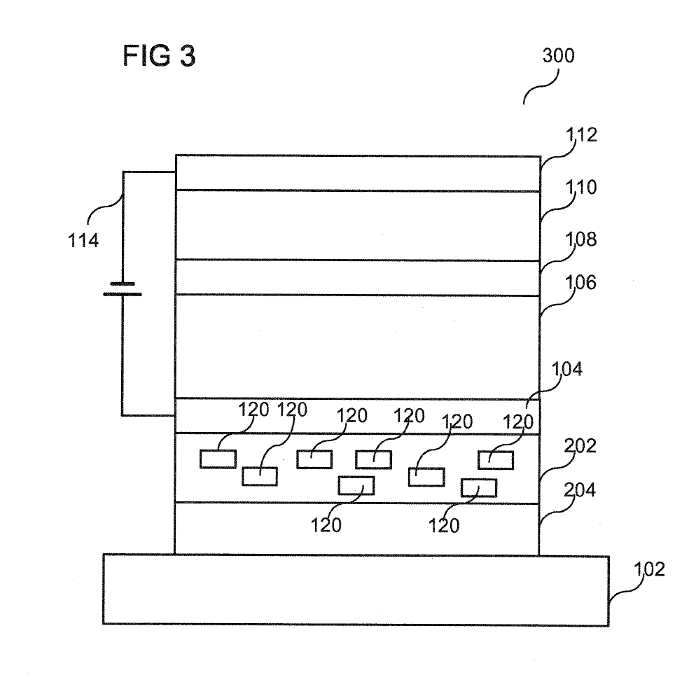

FIG. 3 shows an organic light-emitting diode 300 as an implementation of a light-emitting component in accordance with various embodiments.

The organic light-emitting diode 300 in accordance with FIG. 3 is substantially identical to the organic light-emitting diode 200 in accordance with FIG. 2, for which reason only the differences between the organic light-emitting diode 300 in accordance with FIG. 3 and the organic light-emitting diode 200 in accordance with FIG. 2 are explained in greater detail below; with regard to the remaining elements of the organic light-emitting diode 300 in accordance with FIG. 3, reference is made to the above explanations concerning the organic light-emitting diode 200 in accordance with FIG. 2 and the organic light-emitting diode in accordance with FIG. 1.

Furthermore, the organic light-emitting diode 300 in accordance with FIG. 3 additionally includes the substrate 102. The mirror layer structure 204 is arranged on or above the substrate 102 in accordance with these embodiments.

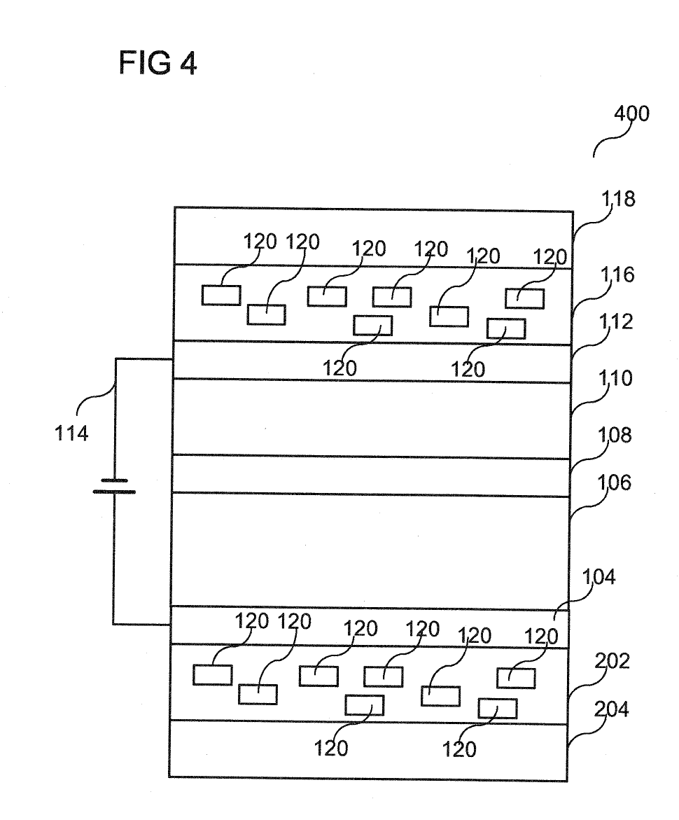

FIG. 4 shows an organic light-emitting diode 400 as an implementation of a light-emitting component in accordance with various embodiments.

The organic light-emitting diode 400 in accordance with FIG. 4 is substantially identical to the organic light-emitting diode 100 in accordance with FIG. 1, for which reason only the differences between the organic light-emitting diode 400 in accordance with FIG. 4 and the organic light-emitting diode 100 in accordance with FIG. 1 are explained in greater detail below; with regard to the remaining elements of the organic light-emitting diode 400 in accordance with FIG. 4, reference is made to the above explanations concerning the organic light-emitting diode 100 in accordance with FIG. 1.

In relation to the elements of the organic light-emitting diode 100 in accordance with FIG. 1 (it should be noted that the substrate 102 is omitted in these embodiments), in the case of the organic light-emitting diode 400 in accordance with FIG. 4, an additional external cavity is also provided below the first electrode 104.

In these embodiments, the energy source 114 is connected to the first electrical terminal of the first electrode 104 and to the second electrical terminal of the second electrode 112.

The organic light-emitting diode 400 in accordance with FIG. 4 may be formed as a bottom emitter or as a top emitter or as a top and bottom emitter.

In the case of the organic light-emitting diode 400 in accordance with FIG. 4, an additional optically translucent layer structure 204 constructed identically to the optically translucent layer structure 116 of the organic light-emitting diode 100 in accordance with FIG. 1 is additionally arranged below the first electrode 102. Furthermore, an additional mirror layer structure 204 structured identically to the mirror layer structure 118 of the organic light-emitting diode 100 in accordance with FIG. 1 is additionally arranged below the optically translucent layer structure 204.

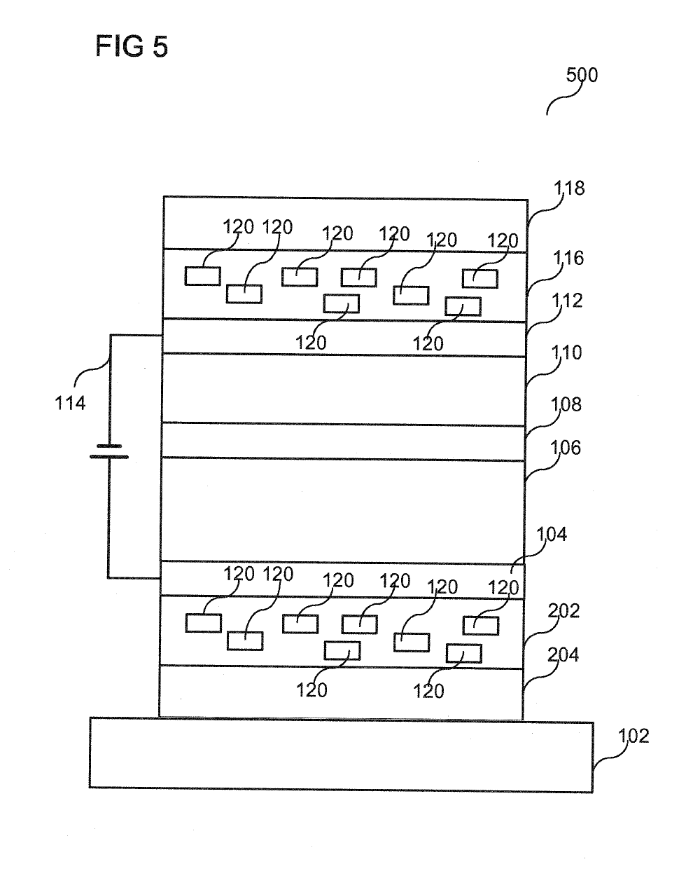

FIG. 5 shows an organic light-emitting diode 500 as an implementation of a light-emitting component in accordance with various embodiments.

The organic light-emitting diode 400 in accordance with FIG. 5 is substantially identical to the organic light-emitting diode 400 in accordance with FIG. 4, for which reason only the differences between the organic light-emitting diode 500 in accordance with FIG. 5 and the organic light-emitting diode 400 in accordance with FIG. 4 are explained in greater detail below; with regard to the remaining elements of the organic light-emitting diode 500 in accordance with FIG. 5, reference is made to the above explanations concerning the organic light-emitting diode 400 in accordance with FIG. 4, the organic light-emitting diode 200 in accordance with FIG. 2, and the organic light-emitting diode 100 in accordance with FIG. 1.

Furthermore, the organic light-emitting diode 500 in accordance with FIG. 5 additionally includes the substrate 102. The mirror layer structure 204 is arranged on or above the substrate 102 in accordance with these embodiments.

Therefore, illustratively, the one or the plurality of external cavities may be arranged below the OLED (i.e. on the substrate) and/or on the OLED (i.e. on the top side). The one or the plurality of external cavities may in turn be constructed from one or a plurality of matrix materials, such as have been described above, including one or a plurality of photoluminescence materials (e.g. chromophores) and scatterers.

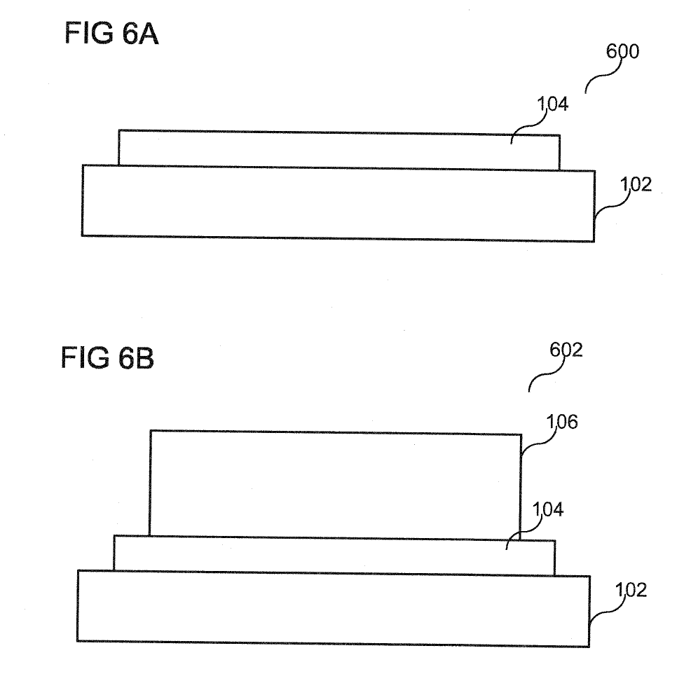

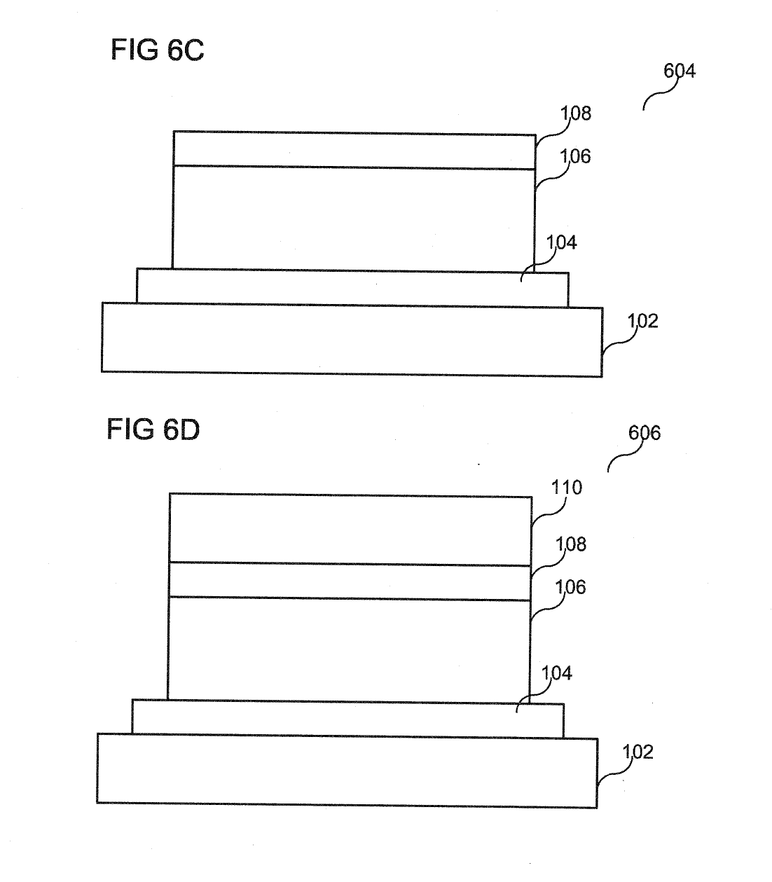

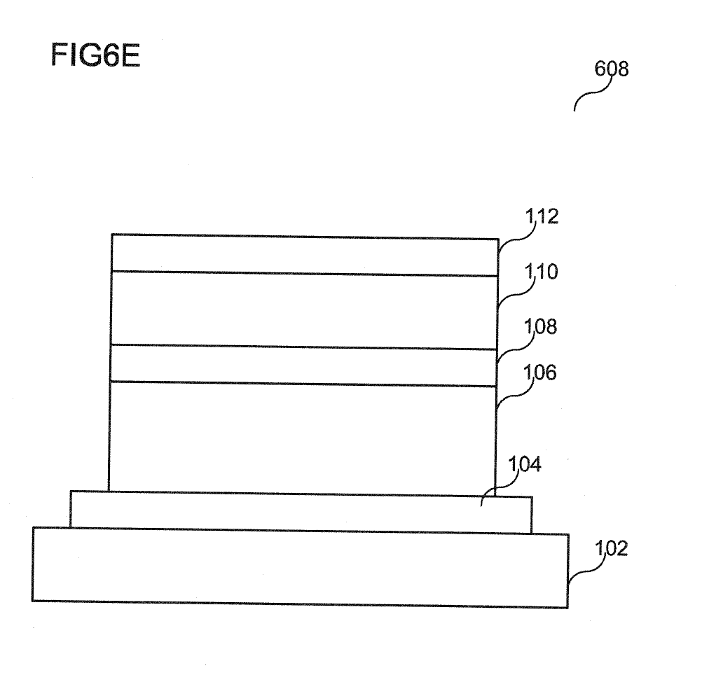

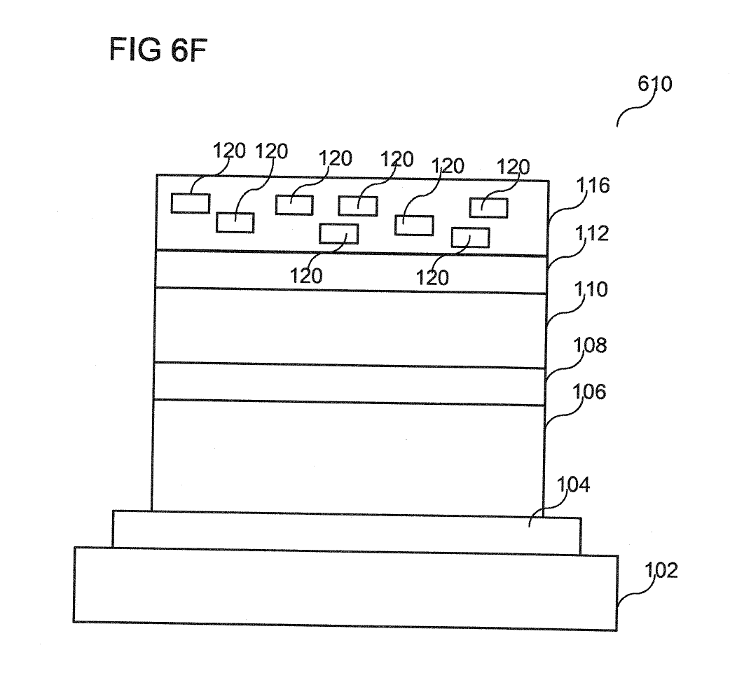

FIG. 6A to FIG. 6F show the light-emitting component 100 in accordance with various embodiments at different points in time during the production of said component. The other light-emitting components 200, 300, 400, 500 are produced in a corresponding manner.

FIG. 6A shows the light-emitting component 100 at a first point in time 600 during the production of said component.

At this point in time, the first electrode 104 is applied to the substrate 102, for example deposited onto said substrate, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

In various embodiments, a plasma enhanced chemical vapor deposition (PE-CVD) method may be used as CVD method. In this case, a plasma may be generated in a volume above and/or around the element to which the layer to be applied is intended to be applied, wherein at least two gaseous starting compounds are fed to the volume, said compounds being ionized in the plasma and excited to react with one another. The generation of the plasma may make it possible that the temperature to which the surface of the element is to be heated in order to make it possible to produce the dielectric layer, for example, may be reduced in comparison with a plasmaless CVD method. That may be advantageous, for example, if the element, for example the light-emitting electronic component to be formed, would be damaged at a temperature above a maximum temperature. The maximum temperature may be approximately 120° C. for example in the case of a light-emitting electronic component to be formed in accordance with various embodiments, such that the temperature at which the dielectric layer for example is applied may be less than or equal to 120° C. and for example less than or equal to 80° C.

FIG. 6B shows the light-emitting component 100 at a second point in time 602 during the production of said component.

At this point in time, the one or the plurality of hole-conducting layers 106 is or are applied to the first electrode 104, for example deposited onto said first electrode, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 6C shows the light-emitting component 100 at a third point in time 604 during the production of said component.

At this point in time, the one or the plurality of emitter layers 108 is or are applied to the one or the plurality of hole-conducting layers 106, for example deposited onto said hole-conducting layer(s), for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 6D shows the light-emitting component 100 at a fourth point in time 606 during the production of said component.

At this point in time, the plurality of further organic functional layers 110 is or are applied to the one or the plurality of emitter layers 108, for example deposited onto said layer(s), for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 6E shows the light-emitting component 100 at a fifth point in time 608 during the production of said component.

At this point in time, the second electrode 112 is applied to the one or the plurality of further organic functional layers 110 (if present) or to the one or the plurality of emitter layers 108, for example deposited onto said layer(s), for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 6F shows the light-emitting component 100 at a sixth point in time 610 during the production of said component.

At this point in time, the optically translucent layer structure 116 is applied to the second electrode 112, the photoluminescence material 120 being introduced into the optically translucent layer structure 116.

This may take place in different ways:
1. In accordance with one implementation, the material or materials, for example organic materials, may be vapor-deposited onto the second electrode 112, wherein the photoluminescence material 120 is embedded in situ into the material of the optically translucent layer structure 116. The mirror layer structure 118 may subsequently be vapor-deposited, wherein both vapor deposition processes may be carried out in the same machine.
2. In accordance with a further implementation, the material or materials, for example organic materials, may be applied on the second electrode 112 (or a thin-film barrier applied thereon for chemically protecting the second electrode 112) wet-chemically. In this implementation, the photoluminescence material 120 may be (partly locally) mixed (dispersed) into the material applied wet-chemically.

It should be pointed out that for the case where the optically translucent layer structure 116, 204 has a plurality of layers, the photoluminescence material 120 may be introduced in one or a plurality of the layers, but need not be introduced in all the layers. In this way, for example, the distance between the photoluminescence material 120 and the mirror layer structure 118, 204 may be defined in a simple manner. This may lead to an amplification of the photoluminescence and/or to an improvement in the color conversion efficiency. Furthermore, a setting of the viewing angle dependence may be made possible.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A light-emitting component, comprising:
a first electrode;
an organic electroluminescent layer structure on or above the first electrode;
a second translucent electrode on or above the organic electroluminescent layer structure;
an optically translucent layer structure on or above the second electrode, wherein the optically translucent layer structure includes photoluminescence material; and
a mirror layer structure on or above the optically translucent layer structure.

2. The light-emitting component as claimed in claim 1, further comprising one or a plurality of layers selected from:
an electrically insulating layer between the second electrode and the optically translucent layer structure; and/or
a barrier or encapsulation layer between the second electrode and the optically translucent layer structure.

3. A light-emitting component, comprising:
a mirror layer structure;
an optically translucent layer structure on or above the mirror layer structure, wherein the optically translucent layer structure includes photoluminescence material;
a first translucent electrode on or above the optically translucent layer structure;
an organic electroluminescent layer structure on or above the first electrode; and
second electrode on or above the organic electroluminescent layer structure.

4. The light-emitting component as claimed in claim 3, further comprising one or a plurality of layers selected from:
an electrically insulating layer between the first electrode and the optically translucent layer structure; and/or
an encapsulation or barrier layer between the first electrode and the optically translucent layer structure.

5. The light-emitting component as claimed in claim 1,
wherein the photoluminescence material includes a material from at least one of the following material groups:
organic dye molecules;
inorganic phosphors; and/or
nanodots or nanoparticles.

6. The light-emitting component as claimed in claim 1,
wherein the optically translucent layer structure additionally includes one or a plurality of scattering materials.

7. The light-emitting component as claimed in claim 1,
designed as an organic light-emitting diode, or as an organic light-emitting transistor.

8. A method for producing a light-emitting component, the method comprising:
providing a first electrode;
forming an organic electroluminescent layer structure on or above the first electrode;
forming a second translucent electrode on or above the organic electroluminescent layer structure;
forming an optically translucent layer structure on or above the second electrode, wherein photoluminescence material is formed in the optically translucent layer structure; and
forming a mirror layer structure on or above the optically translucent layer.

9. The method as claimed in claim 8, further comprising:
forming an electrically insulating layer on or above the second electrode;
wherein the optically translucent layer structure is formed on or above the electrically insulating layer.

10. A method for producing a light-emitting component, the method comprising:
providing a mirror layer structure;
forming an optically translucent layer structure on or above the mirror layer structure, wherein photoluminescence material is formed in the optically translucent layer structure;
forming a first translucent electrode on or above the optically translucent layer structure;
forming an organic electroluminescent layer structure on or above the first electrode; and
forming a second electrode on or above the organic electroluminescent layer structure.

11. The method as claimed in claim 10, further comprising at least one of:
forming an electrically insulating layer on or above the optically translucent layer structure;
wherein the first electrode is formed on or above the electrically insulating layer; and/or
forming an encapsulation or barrier layer between the first electrode and the optically translucent layer structure.

12. The method as claimed in claim 8, wherein a material from at least one of the following material groups is used as photoluminescence material:
organic dye molecules;
inorganic phosphors; and/or
nanodots or nanoparticles.

13. The method as claimed in claim 8, wherein the optically translucent layer structure additionally includes one or a plurality of scattering materials.

14. The method as claimed in claim 8, wherein the optically translucent layer structure is formed by means of vapor deposition.

15. The method as claimed in claim 14,
wherein the photoluminescence material is embedded in situ into the optically translucent layer structure.

16. The method as claimed in claim 8, wherein the optically translucent layer structure is formed by means of a wet-chemical process.

17. The method as claimed in claim 8, wherein the light-emitting component is designed as an organic light-emitting diode, or as an organic light-emitting transistor.

18. The light-emitting component as claimed in claim 3,
wherein the photoluminescence material includes a material from at least one of the following material groups:
organic dye molecules;
inorganic phosphors; and/or
nanodots or nanoparticles.

19. The light-emitting component as claimed in claim 3,
wherein the optically translucent layer structure additionally includes one or a plurality of scattering materials.

20. The light-emitting component as claimed in claim 3,
designed as an organic light-emitting diode, or as an organic light-emitting transistor.

21. The method as claimed in claim 10,
wherein a material from at least one of the following material groups is used as photoluminescence material:
organic dye molecules;
inorganic phosphors; and/or
nanodots or nanoparticles.

22. The method as claimed in claim 10,
wherein the optically translucent layer structure additionally includes one or a plurality of scattering materials.

23. The method as claimed in claim 10,
wherein the optically translucent layer structure is formed by means of vapor deposition.

24. The method as claimed in claim 23,
wherein the photoluminescence material is embedded in situ into the optically translucent layer structure.

25. The method as claimed in claim 10,
wherein the optically translucent layer structure is formed by means of a wet-chemical process.

26. The method as claimed in claim 10,
wherein the light-emitting component- is designed as an organic light-emitting diode, or as an organic light-emitting transistor.
